(19) United States
(12) Patent Application Publication
(10) Pub. No.: US 2013/0061915 A1
(43) Pub. Date: Mar. 14, 2013

(54) THIN FILM SOLAR CELLS AND MANUFACTURING METHOD THEREOF

(71) Applicants: Seung-Yeop Myong, Seoul (KR); La-Sun Jeon, Seoul (KR)

(72) Inventors: Seung-Yeop Myong, Seoul (KR); La-Sun Jeon, Seoul (KR)

(21) Appl. No.: 13/608,889

(22) Filed: Sep. 10, 2012

(30) Foreign Application Priority Data
Sep. 9, 2011 (KR) 10-2011-0092018

(51) Int. Cl. H01L 31/075

(52) U.S. Cl. 136/255

(57) ABSTRACT

A thin film silicon solar cell including: a front transparent electrode stacked on a transparent insulating substrate; a p-type layer stacked on the front transparent electrode; an i-type photoelectric conversion layer stacked on the p-type layer; an n-type Saver stacked, on the i-type photoelectric conversion layer; and a metal back electrode layer stacked on the n-type layer, wherein the n-type layer includes: an n-type amorphous silicon first n layer which is stacked on the i-type photoelectric conversion layer and has a thickness of 3 nm to 7 nm; and an n-type silicon second n layer which is stacked on the first n layer and has a thickness of 15 nm to 30 nm and is more highly hydrogen-diluted than the first n layer.

### CROSS-REFERENCE TO RELATED APPLICATIONS

This application claims the benefit of Korean Patent Application No. 10-2011-0092018, filed Sep. 9, 2011, the entirety of which is hereby incorporated by reference.

### FIELD OF THE INVENTION

This embodiment relates to a thin film silicon solar cell and a manufacturing method thereof, and more particularly to a thin film silicon solar cell, which has improved photoelectric conversion efficiency, and a manufacturing method thereof.

### BACKGROUND OF THE INVENTION

An amorphous silicon (a-Si) solar cell was first developed in 1976 and has been being researched because hydrogenated amorphous silicon (a-Si:H) has a high photosensitivity in the visible light region, easiness to adjust an optical band gap, and a large area processability at a low cost and low temperature.

However, it was discovered that the hydrogenated amorphous silicon (a-Si:H) has Stabler-Wronski effect. That is to say, the hydrogenated amorphous silicon (a-Si:H) has a fatal defect of being seriously degraded by light irradiation.

Therefore, many efforts have been made to reduce the Stabler-Wronski effect of amorphous silicon materials. As a result, methods for performing hydrogen (H₂) dilution on SiH₄ were developed. Hydrogenated intrinsic microcrystalline silicon (i-μc-Si:H), hydrogenated intrinsic nanocrystalline silicon (i-nc-Si:H), hydrogenated intrinsic protocrystalline silicon (i-pc-Si:H) and the like, all of which are manufactured through the hydrogen dilution and have less degradation by light irradiation, are popular as a light absorber of a thin film solar cell.

Further, a multi-junction solar cell which maximizes the absorption of light through a combination of the various optical band gaps of the aforementioned silicon based materials is actively being developed.

Meanwhile, development of a high efficient thin film silicon solar cell absolutely requires not only the light absorber having less degradation but also a p-type window layer which generates a strong electric field in the light absorber and absorbs minimal visible light by itself.

For this purpose, there is a requirement that the p-type window layer should have a wide optical band gap and high conductivity.

In Osaka University, Japan in 1982, a hydrogenated p-type amorphous silicon carbide (p-a-SiC:H) thin film which has been deposited by the hydrogen dilution was used as a window layer of the amorphous silicon solar cell, so that hetero-junction has been formed on a p/i interface. This was a major milestone for improving the efficiency of the solar cell and is now widely used as a window layer.

However, an abrupt hetero-junction of a p-type layer and an i-type layer (p-a-SiC:H/i-a-Si:H) increases defect density at the interface, thereby causing significant recombination loss of a photogeneration carrier.

When the optical band gap is increased by being combined with carbon, the conductivity becomes low. Therefore, there is a limit to achieve a high efficiency.

Thus, the recombination loss reduction of the hetero-junction p/i interface has become a core technology of a high efficiency thin film silicon solar cell development and has been being actively researched. As part of the research, various buffer layers have been developed for the purpose of the p/i interface improvement of the amorphous silicon solar cell.

However, because a dangling bond defect density of a graded band gap i-a-SiC:H buffer layer which is deposited by the hydrogen dilution is significant, the recombination loss at the p/i interface is still large. Also, a low conductivity of the buffer layer causes the fill factor(FF) of the solar cell to be reduced.

Likewise, the abrupt hetero-junction or weak electric field at an n/i interface brings about the recombination loss and degrades the efficiency. Therefore, it is necessary to achieve a high efficiency through the improvement of long wavelength responses by reducing the recombination at the n/i interface.

In the mean time, a single-junction thin film silicon solar cell has its own limited attainable performance. Accordingly; a double-junction thin film silicon solar cell or a triple-junction thin film silicon solar cell, each of which has a plurality of stacked unit cells, has been developed, and thereby pursuing a high stabilized efficiency after light irradiation.

### SUMMARY OF THE INVENTION

One aspect of the present invention is a thin film silicon solar cell including: a front transparent electrode stacked on a transparent insulating substrate; a p-type layer stacked on the front transparent electrode; an i-type photoelectric conversion layer stacked on the p-type layer; an n-type layer stacked on the i-type photoelectric conversion layer; and a metal back electrode layer stacked on the n-type layer. The n-type layer includes: an n-type amorphous silicon first n layer which is stacked on the i-type photoelectric conversion layer and has a thickness of 3 nm to 7 nm; and an n-type silicon second n layer which is stacked on the first n layer and has a thickness of 15 nm to 30 nm and is more highly hydrogen-diluted than the first n layer.

Another aspect of the present invention is a thin film silicon solar cell including: a front transparent electrode stacked on a transparent insulating substrate; a first unit cell which is stacked on the transparent electrode and includes a p-type layer, an i-type photoelectric conversion layer and an n-type layer; a second unit cell which is stacked on the first unit cell and includes a p-type layer, an i-type photoelectric conversion layer and an n-type layer; and a metal back electrode layer stacked on the second unit cell. The n-type layer of the second unit cell includes: an n-type amorphous silicon first n layer which is stacked on the i-type photoelectric conversion layer of the second unit cell and has a thickness of 3 nm to 7 nm; and an n-type silicon second n layer which is stacked on the first n layer and has a thickness of 15 nm to 30 nm and is more highly hydrogen-diluted than the first n layer.

### BRIEF DESCRIPTION OF THE DRAWINGS

FIG. 1 is a cross sectional view of a conventional single-junction amorphous silicon solar cell;

FIG. 2 is a cross sectional view of a single-junction amorphous silicon solar cell according to an embodiment of the present invention;

FIG. 3 is a graph showing quantum efficiency spectra of the single-junction amorphous silicon solar cell according to the embodiment of the present invention;

FIG. 4 is a cross sectional view of a multi-junction thin film silicon solar cell according to another embodiment of the present invention;

FIG. 5 is a graph for describing a process of obtaining a crystal volume fraction in accordance with Raman analysis;

FIG. 6 is a graph showing Raman analysis in accordance with the embodiment of the present invention;

FIG. 7 is a flowchart showing a manufacturing method for the amorphous silicon solar cell according to the embodiment of the present invention;

FIG. 8 is a flowchart showing a manufacturing method for a first n layer according to the embodiment of the present invention; and

FIG. 9 is a flowchart showing a manufacturing method for a second n layer according to the embodiment of the present invention.

### DETAILED DESCRIPTION OF THE INVENTION

The following detailed description of the present invention shows a specified embodiment of the present invention and will be provided with reference to the accompanying drawings. The embodiment will be described in enough detail that those skilled in the art are able to embody the present invention. It should be understood that various embodiments of the present invention are different from each other and need not be mutually exclusive. For example, a specific shape, structure and properties, which are described in this disclosure, may be implemented in other embodiments without departing from the spirit and scope of the present invention with respect to one embodiment. Also, it should be noted that positions or placements of individual components within each disclosed embodiment may be changed without departing from the spirit and scope of the present invention. Therefore, the following detailed description is not intended to be limited. If adequately described, the scope of the present invention is limited only by the appended claims of the present invention as well as all equivalents thereto. Similar reference numerals in the drawings designate the same or similar functions in many aspects.

Hereafter, exemplary embodiments of the present invention will be described in detail with reference to the accompanying drawings in order that the present invention may be easily implemented by those skilled in the art.

FIG. 1 is a cross sectional view of a conventional single-junction p-i-n type amorphous silicon solar cell.

As shown in FIG. 1, a thin film silicon solar cell is formed to have a structure in which a plurality of unit cells are electrically connected in series to each other on a glass substrate or a transparent plastic substrate (hereafter, referred to as a transparent substrate).

The thin film silicon solar cell includes a front transparent electrode which is formed on the transparent insulating substrate and has a surface unevenness formed thereon, a hydrogen-diluted p-type amorphous silicon carbide (p-a-SiC:H) layer which is formed on the front transparent electrode, an i-type photoelectric conversion layer, an n-type layer, a back reflector and a metal back electrode layer, all of which are sequentially stacked on the p-type layer in the order listed.

The p-type layer includes a slightly hydrogen-diluted amorphous silicon carbide (p-a-SiC:H) window layer (hereafter, referred to as a p-type window layer) on the front transparent electrode. Also, the p-type layer may further include a relatively highly hydrogen-diluted amorphous silicon carbide (p-a-SiC:H) buffer layer (hereafter, referred to as a p-type buffer layer) on the p-type window layer in order to increase the quantum efficiency of the solar cell and to reduce the electron-hole recombination loss.

Here, for the purpose of the high efficiency of the solar cell, the slightly hydrogen-diluted p-type window layer and the relatively highly hydrogen-diluted p-type buffer layer having a low boron doping concentration and a low carbon concentration may be constructed.

The p-type window layer formed on the front transparent electrode may have a slightly hydrogen-diluted p-type amorphous silicon carbide (p-a-SiC:H) structure which is formed by being deposited under the condition that a silane concentration is high and a carbon concentration and boron (B) doping concentration are relatively high.

The p-type buffer layer formed at a p/i interface may have a highly hydrogen-diluted p-type amorphous silicon carbide (p-a-SiC:H) structure which is formed by being deposited under the condition that the silane concentration is relatively lower than that of the p-type window layer and a carbon concentration and boron (B) concentration are low.

In order to maximize the light trapping effect on the n-type layer, the back reflector which is generally formed of ZnO may be prepared by CVD or sputtering.

The metal back electrode layer functions as a back electrode of a unit cell (not shown) as well as reflects light which has transmitted through the solar cell layer. The metal back electrode layer may be formed of ZnO, Ag or the like by CVD or sputtering.

However, the conventional single-junction p-i-n type amorphous silicon solar cell has limited photoelectric conversion efficiency. The present invention provides an amorphous silicon solar cell having more improved efficiency than the conventional p-i-n type amorphous silicon solar cell.

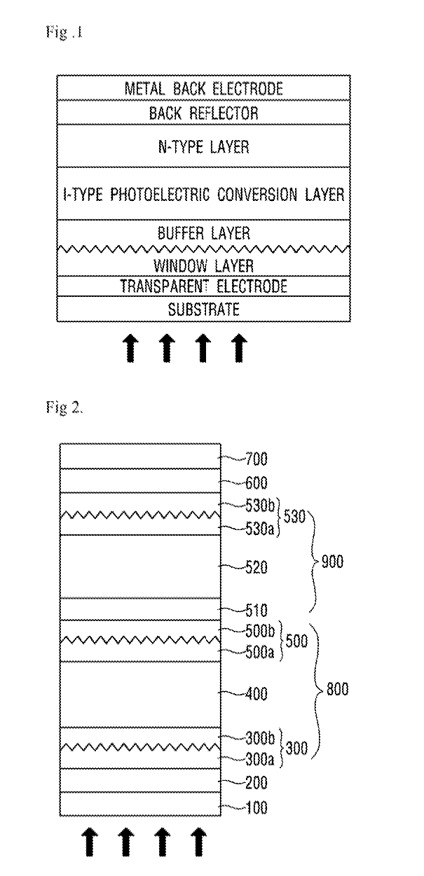

FIG. 2 is a cross sectional view of a single-junction p-i-n type amorphous silicon thin film solar cell according to an embodiment of the present invention.

As shown in FIG. 2, the single-junction p-i-n type amorphous silicon solar cell according to the embodiment of the present invention includes a front transparent electrode 20 which is formed on a transparent insulating substrate 10 and has surface unevenness formed thereon, a hydrogen-diluted p-type amorphous silicon carbide (p-a-SiC:H) p-type layer 30 which is formed on the front transparent electrode 20, an i-type photoelectric conversion layer 40 on the p-type layer 30, a relatively slightly hydrogen-diluted n-type amorphous, silicon first n layer 50a which is stacked on the i-type photoelectric conversion layer 40, an n-type silicon second n layer 50b which is stacked on the first n layer 50a and is relatively more highly hydrogen-diluted than the first n layer 50a, a back reflector 60 and a metal back electrode layer 70.

Here, the p-type layer 30 includes a slightly hydrogen-diluted p-type amorphous silicon carbide (p-a-SiC:H) window layer 30a on the front transparent electrode 20. The p-type layer 30 may further include a relatively highly hydrogen-diluted p-type amorphous silicon carbide (p-a-SiC:H) buffer layer 30b on the p-type window layer 30a in order to increase the quantum efficiency of the solar cell and to reduce electron-hole recombination loss.

Referring to FIG. 2, the substrate 10 of the solar cell according to the embodiment of the present invention may be a flexible substrate such as metal foil or polymer or may be an inflexible substrate such as glass.

The transparent electrode 20 may be formed of a transparent conductive oxide such as ZnO, SnO₂ and IZO. When transparent conductive oxide is formed by chemical vapor deposition (CVD), the unevenness may be formed on the surface of the transparent conductive oxide. The surface unevenness of the transparent conductive oxide improves the light trapping effect.

Referring to FIG. 2, sunlight is absorbed by i-type photoelectric conversion layer 40 of the p-i-n junction. The absorbed sunlight is converted into electron-hole pairs. The photo-generated electron-hole pairs traverse the i-type photoelectric conversion layer 40. An electric field formed between the p-type layer 30 and the n-type layer 50 causes the electrons to move to the n-type layer 50 and causes the holes to move to the p-type layer 30, and thereby generating a current.

Since the p-type layer 30 including the p-type window layer 30a and the p-type buffer layer 30b has been already described, a description thereof will be omitted.

Here, the slightly hydrogen-diluted n-type amorphous silicon first n layer 50a may be formed of a relatively slightly hydrogen-diluted amorphous silicon layer. The second n layer 50b may be formed of either a relatively highly hydrogen-diluted amorphous silicon layer or a relatively highly hydrogen-diluted microcrystalline silicon layer.

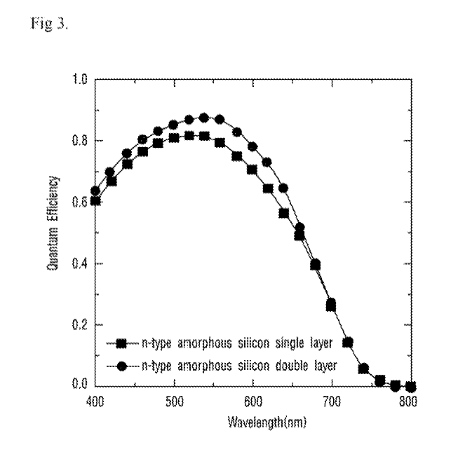

FIG. 3 is a graph showing quantum efficiency spectra of the single-junction amorphous silicon solar cells according to the embodiment of the present invention.

Referring to FIG. 3, it can be seen that an external quantum efficiency of the silicon solar cell according to the embodiment of the present invention is higher in a long wavelength region of visible light than a conventional solar cell including n-type amorphous silicon single layer.

The following Table 1 shows the performances of the single-junction amorphous silicon solar cell according to the structure of the n-type layer.

TABLE 1

| | | Jsc | fill factor | efficiency |
|---|---|---|---|---|
| structure of n-type layer | Voc (V) | (mA/cm²) | (FF) | Eff (%) |
| amorphous silicon | 0.897 | 13.9 | 0.737 | 9.21 |
| n layer (20 nm) | | | | |
| highly hydrogen-diluted | 0.914 | 14.5 | 0.658 | 8.72 |
| n layer (20 nm) | | | | |
| amorphous silicon n layer | 0.900 | 15.1 | 0.740 | 10.0 |
| (5 nm)/highly hydrogen- | | | | |
| diluted n layer (20 nm) | | | | |
| amorphous silicon (5 nm)/ | 0.884 | 14.8 | 0.736 | 9.64 |
| highly hydrogen-diluted | | | | |
| n layer (30 nm) | | | | |

Referring to FIG. 3 and Table 1 the quantum efficiency for the cell having a double layer comprised of both the 5 nm-thick slightly hydrogen-diluted n-type amorphous silicon (n-a-Si:H) layer and the 20 nm-thick highly hydrogen-diluted n-type silicon layer is higher in the long wavelength region of visible light than that for the cell having only the 20 nm-thick slightly hydrogen-diluted n-type amorphous silicon (n-a-Si:H) layer. This is because the highly hydrogen-diluted, n-type silicon layer has a higher electrical conductivity than that of the slightly hydrogen-diluted n-type amorphous silicon (n-a-Si:H) layer, and thus the collection efficiency is improved.

When oxygen in the air diffuses to the i-type photoelectric conversion layer 40, i-type photoelectric conversion layer 40 is changed into the weakly n-type layer because oxygen acts as a shallow donor. The n-type amorphous silicon layer has a high resistance to the diffusion of oxygen in the air into the solar cell.

When the n-type layer is comprised of only the highly hydrogen-diluted n-type silicon layer, the highest open circuit voltage is obtained due to the high electrical conductivity. However, interface properties are deteriorated at the n/i interface due to the sudden change of Fermi level. That is, the high recombination of photo-generated carriers at the n/i interface causes the fill factor (FF) to be remarkably reduced. Contrarily, when the slightly hydrogen-diluted n-type amorphous silicon (n-a-Si:H) layer is even thinly interposed: between the highly hydrogen-diluted n-type silicon layer and the i-type photoelectric conversion layer 40, the recombination is considerably decreased at the n/i interface. As a result, the fill factor (FF) is prevented from being reduced, and the open circuit voltage and short circuit current are maintained higher. Consequently, the efficiency is enhanced.

The thickness of the slightly hydrogen-diluted n-type amorphous silicon first, n layer 50a should be 3 nm to 7 nm. If the thickness is too small the first n layer 50a is not able to correctly perform a function to reduce the recombination at the n/i interface. If the thickness is too large, the light absorption by the slightly hydrogen-diluted n-type amorphous silicon first n layer 50a increases and the short circuit current is reduced. Furthermore, a series resistance is increased. As a result, the fill factor (FF) is reduced and the conversion efficiency is reduced.

The thickness of the highly hydrogen-diluted n-type silicon second n layer 50b should be 15 nm to 30 nm. If the thickness is too small, the electrical conductivity is low and a strong electric field by an intrinsic light absorber cannot be formed. Thus, the open circuit voltage of the solar cell becomes lower. If the thickness is too large, the open circuit voltage is reduced and the light absorption by the highly hydrogen-diluted n-type silicon second n layer 50b is increased. As a result, the short circuit current is reduced and the conversion efficiency is reduced.

Here, for the purpose of high efficiency of the solar cell, the highly hydrogen-diluted n-type silicon second n layer 50b is relatively more highly hydrogen-diluted than the slightly hydrogen-diluted n-type amorphous silicon first n layer 50a. As a result, the hydrogen concentration of the second n layer 50b is higher than that of the first n layer 50a. The higher the hydrogen dilution is, the more the doping efficiency is enhanced. Therefore, an impurity concentration for maintaining an adequate electrical conductivity is reduced. Accordingly, the impurity concentration of the second n layer 50b is less than that of the first n layer 50a.

The impurity concentrations of the first n layer 50a and the second n layer 50b may be equal to or higher than 1×10¹⁹/cm³ and equal to or less than 1×10²¹/cm³. When the impurity concentration is less than 1×10¹⁹/cm³, the electrical conductivity becomes lower, and the open circuit voltage and the fill factor (FF) are reduced. When the impurity concentration is higher than 1×10²¹/cm³, the light absorption increases and the short circuit current is reduced. The first n layer 50a and the second n layer 50b may include phosphorus (P) as a doping impurity.

Hydrogen contents of the first n layer 50a and the second n layer 50b may be equal to or more than 5 atomic % and equal to or less than 25 atomic %, When the hydrogen content, is too low, a combination density of the n layer becomes higher and the recombination is increased. When the hydrogen content is too large, microvoids within the thin film are increased and the n layer becomes porous, and thus the recombination is increased.

In order to maximize the light trapping effect on the n-type layer 50, the back reflector 60 which is generally formed of ZnO may be prepared by CVD or sputtering.

The metal back, electrode layer 70 functions as a back electrode of a unit cell (not shown) as well as reflects light which has transmitted through the solar cell layer. The metal back electrode layer may be formed of ZnO, Ag or the like by CVD or sputtering.

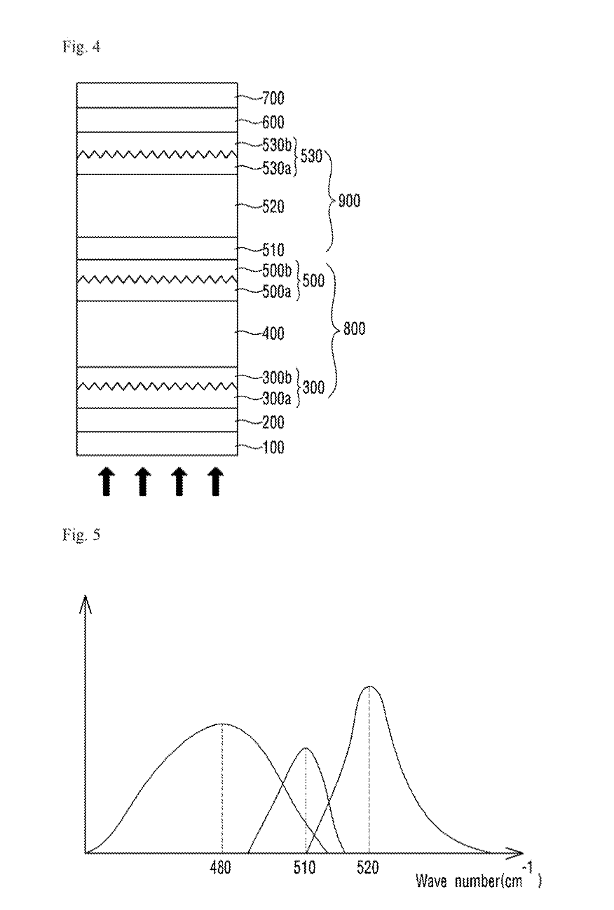

FIG. 5 shows a measurement result of Raman spectroscopy using HeNe laser with a wavelength of 633 nm.

The highly hydrogen-diluted n-type silicon second n layer 50b may be an amorphous silicon layer or may include microcrystalline silicon.

Here, a crystal volume fraction of the second n layer 50b may be equal to or greater than 0% and equal to or less than 25%. The greater the crystal volume fraction of the second n layer 50b is, the more the resistance increase caused by excessive amorphization of the second n layer 50b is prevented. When the crystal volume fraction of the second n layer 50b is designed to be greater than 25%, it is required that a hydrogen dilution ratio of the second n layer 50b should be very high or the thickness of the second n layer 50b should be very large. Therefore, the manufacturing cost may rise or the short circuit current may be reduced by the increase in light absorption of the second n layer 50b.

FIG. 5 is a graph for describing a process for the calculation of the crystal volume fraction. The crystal volume fraction is obtained by the following equation:

crystal volume fraction (%)=[(A₅₁₀+A₅₂₀)/(A₄₈₀+A₅₁₀+A₅₂₀)]*100

Here, A; is an area of a component peak in the vicinity of i cm⁻¹. For example, three peaks shown in FIG. 5 are obtained by performing Raman spectroscopy on any layer of the solar cell. The area of component peak in the vicinity of 480 cm⁻¹ obtained by means of Gaussian peak fitting corresponds to the amorphous silicon TO mode. The area of component peak in the vicinity of 510 cm⁻¹ obtained by means of Gaussian peak fitting corresponds to a small grain or grain boundary defect. The area of component peak in the vicinity of 520 cm⁻¹ obtained by means of Gaussian peak fitting corresponds to the crystalline silicon TO mode.

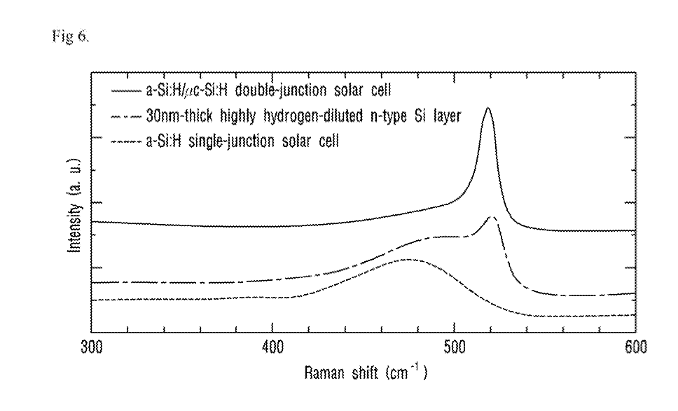

In FIG. 6, a 30 nm-thick highly hydrogen-diluted n-type silicon thin film formed on a glass substrate has a phase of microcrystalline silicon having a crystal volume fraction of about 42%. However, the Raman spectrum measured from the n layer of the back side of the single-junction amorphous silicon solar cell does not show any peak related to a crystalline silicon grain near 510 cm⁻¹ or 520 cm⁻¹ and show only a peak related to a crystalline silicon grain near 480 cm⁻¹, and thus a complete amorphous silicon phase having a crystal, volume fraction almost close to 0% is shown. This is because the i-type photoelectric conversion layer and the slightly hydrogen-diluted n-type amorphous silicon first n layer 50a prevent the crystallization of the thin second n layer 50b.

In the embodiment, a refractive index at a wavelength of 632 nm for the slightly hydrogen-diluted n-type amorphous silicon first n layer is 4.1 and a refractive index at a wavelength of 632 nm for the highly hydrogen-diluted n-type silicon second n layer 50b is 3.6. The n-type layer 50 is matched such that the refractive index of the n-type layer 50 becomes less toward the back reflector (refractive index of 2.0) from the i-type photoelectric conversion layer (refractive index of 4.2). Therefore, the n-type layer 50 enhances internal reflection and contributes, as shown in FIG. 3, the improvement of the quantum efficiency in the long wavelength region of visible light. A non-silicon element, which is a medium for reducing the retractive index, may be included in highly hydrogen-diluted n-type silicon second n layer 50b so as to enhance internal reflection.

An average content of the non-silicon element included in the highly hydrogen-diluted n-type silicon second n layer 50b may be equal to or more than 10 atomic % and equal to or less than 50 atomic %. The non-silicon element may include carbon, nitrogen, oxygen and the like. When the average content of the non-silicon element is equal to or more than 10 atomic %, the refractive index of the highly hydrogen-diluted n-type silicon second n layer 50b becomes less and the internal reflection is effectively enhanced.

When the average content of the non-silicon element is unnecessarily large, the vertical electrical conductivity of the highly hydrogen-diluted n-type silicon second n layer 50b may be reduced. Therefore, in the embodiment of the present invention, when the average content of the non-silicon element is equal to or less than 50 atomic %, the vertical electrical conductivity of the highly hydrogen-diluted n-type silicon second h layer 50b is appropriately maintained so that the fill factor and open circuit voltage of the solar cell are prevented from being reduced.

As such, in the single-junction amorphous silicon solar cell according to the embodiment of the present invention, the n-type layer 50 includes the first n layer 50a and the second n layer 50b, and thus the photoelectric conversion efficiency is increased. Meanwhile, no matter how much degradation by light irradiation is reduced, there is a limit to the efficiency of the single-junction thin film silicon solar cell. Thus, high stabilized efficiency can be obtained by constructing either a double-junction thin film silicon solar cell formed by stacking a top cell based on the amorphous silicon and a bottom cell based on the microcrystalline silicon or a triple-junction thin film silicon solar cell formed by further developing the double-junction solar cell.

The open circuit voltage of the double-junction solar cell or the triple-junction solar cell is a sum of the open circuit voltages of all of unit cells. The short circuit current of the double-junction solar cell or the triple-junction solar cell is a minimum value among the short circuit currents of all of the unit cells. In manufacturing a multi-junction solar cell, an optical band gap of the intrinsic light absorber becomes narrower toward to the bottom cell from the light incident top cell using hetero-junction between the unit cells. The light of broad spectrum is absorbed by separating the spectrum of light absorbed by each cell, and thus the light utilization efficiency is improved. Additionally, since the intrinsic light absorber of the top cell based, on the amorphous silicon which is severely degraded by light irradiation becomes thinner, a degradation ratio is reduced and a high stabilized efficiency can be obtained.

Next, a multi-junction thin film silicon solar cell according to a second embodiment of the present invention will be described.

FIG. 4 shows a multi-junction thin film silicon solar cell according to the second embodiment of the present invention.

Although FIG. 4 shows the double-junction thin film silicon solar cell, triple or more than triple-junction thin film silicon solar cell can be provided. Those skilled in the art can easily change designs of these solar cells. For convenience of description, the double-junction solar cell will be taken as an example for description in FIG. 4. Referring to FIG. 4, a multi-junction p-i-n type thin film silicon solar cell according to the second embodiment of the present invention includes a front transparent electrode 200 which is formed on a transparent insulating substrate 100 and has a surface unevenness formed thereon, a first unit cell 800 stacked on the front transparent electrode 200, a second unit cell 900 stacked on the first unit cell 800, a back reflector 600 and a metal back electrode layer 700.

The substrate 100 of the solar cell according to the embodiment of the present, invention may be a flexible substrate such as metal foil or polymer or may be an inflexible substrate such as glass.

The transparent electrode 200 may be formed of a transparent conductive oxide such as ZnO, SnO₂ and IZO. When transparent conductive oxide is formed by chemical vapor deposition (CVD), an unevenness may be formed on the surface of the transparent conductive oxide. The surface unevenness of the transparent conductive oxide improves the light trapping effect.

In order to maximize the light trapping effect on the second unit cell 900, the back reflector 600 which is generally formed of ZnO may be prepared by CVD or sputtering.

The metal back electrode layer functions as a back electrode of a unit cell (not shown) as well as reflects light which has transmitted through the solar cell layer. The metal back electrode layer may be formed of ZnO, Ag or the like by CVD or sputtering.

The first unit cell 800 includes a hydrogen-diluted p-type amorphous silicon carbide (p-a-SiC:H) p-type layer 300, an i-type photoelectric conversion layer 400 on the p-type layer 300, and an n-type layer 500 stacked on the i-type photoelectric conversion layer 400. The n-type layer 500 may include a hydrogen-diluted n-type amorphous silicon first n layer 500a which is stacked on the i-type photoelectric conversion layer 400, and an n-type silicon second n layer 500b which is stacked on the first n layer 500a and is more highly hydrogen-diluted than the first n layer 500a. The n-type layer 500 does not necessarily include the hydrogen-diluted n-type amorphous silicon layer and the n-type silicon layer which is more highly hydrogen-diluted than the hydrogen-diluted n-type amorphous silicon layer. Those skilled in the art can easily change designs of the layers. Also, the i-type photoelectric conversion layer 400 may be thinner than that of the single-junction solar cell.

The p-type layer 300 includes a slightly hydrogen-diluted p-type amorphous silicon carbide (p-a-SiC:H) window layer 300a on the front transparent electrode 200. Also, the p-type layer 300 may further include a relatively highly hydrogen-diluted p-type amorphous silicon carbide (p-a-SiC:H) buffer layer 300b on the p-type window layer 300a in order to increase the quantum efficiency of the solar cell and to reduce the electron-hole recombination loss.

The second unit cell 900, like the first unit cell 800, has the p-i-n junction. However, the p-type layer of the second unit cell 900 stacked on the second n layer 500b of the first unit cell 800 is a hydrogenated microcrystalline silicon (p-μc-Si:H) layer 510. An i-type photoelectric conversion layer 520 is stacked on the hydrogenated p-type microcrystalline silicon (p-μc-Si:H) layer 510. The i-type photoelectric conversion layer 520 is also a hydrogenated microcrystalline silicon (i-μc-Si:H) layer. An n-type layer 530 is stacked on the i-type photoelectric conversion layer 520. The n-type layer 530 includes a hydrogen-diluted n-type amorphous silicon first n layer 530a and an n-type silicon second n layer 530b. The hydrogen-diluted n-type amorphous silicon first n layer 530a is stacked on the i-type photoelectric conversion layer 520. The n-type silicon second n layer 530b is stacked on the first n layer 530a and is more highly hydrogen-diluted than the first n layer 530a.

Referring to FIG. 4, sunlight is absorbed by the i-type photoelectric conversion layers 400 and 520 of the p-i-n junctions. The absorbed sunlight is converted into electron-hole pairs. The photo-generated electron-hole pairs traverse the i-type photoelectric conversion layers 400 and 520. Electric fields formed in i-type photo-electric conversion layers 400 and 520 cause the electrons to move to each n-type layer and causes the electron-holes to move to each p-type layer, and thereby generating each current. The p-i-n junction of the first unit cell 800 may include an hydrogenated intrinsic amorphous silicon (i-a-Si:H) layer 400. The p-i-n junction of the second unit cell 900 may include a hydrogenated intrinsic microcrystalline silicon (i-μc-Si:H) layer 520. Since the wavelength range may be absorbed by the hydrogenated amorphous silicon is different from that may be absorbed by the hydrogenated microcrystalline silicon, the solar cell is able to absorb a wide range of the spectrum of sunlight. This is more efficient. The hydrogenated amorphous silicon has a band gap wider than that of the hydrogenated microcrystalline silicon. Therefore, sunlight is first absorbed, by the hydrogenated amorphous silicon layer 400, and then is absorbed by the hydrogenated microcrystalline silicon layer 520. Sunlight which is not absorbed by the first unit cell 800 may be absorbed by the second unit cell 900, If the i-type photoelectric conversion layers 400 and 520 are too thick, it may prevent the collection of the photo-generated electrons and holes.

Meanwhile, in the solar cell a tunnel junction is formed between the first unit cell 800 and the second unit cell 900. The electrons collected by the first unit cell 800 and the holes collected by the second unit cell 900 are recombined here. The hydrogen-diluted n-type amorphous silicon first n layer 530a of the second unit cell 900 prevents oxygen in the air from being diffused into the i-type photoelectric conversion layer 520 of the second unit cell 900 and prevents the performance of the solar cell from being deteriorated.

Table 2 shows the efficiency of the double-junction p-i-n type thin film silicon solar cell according to the second embodiment of the present invention.

TABLE 2

| | open | short circuit | | |
|---|---|---|---|---|
| structure of n layer | circuit | current | fill | |
| of the second unit | voltage | Jsc | factor | efficiency |
| cell (bottom cell) | Voc (V) | (mA/cm²) | (FF) | Eff (%) |
| n-type amorphous silicon | 1.30 | 11.7 | 0.684 | 10.4 |
| (n-a-Si:H) layer (35 nm) | | | | |
| highly hydrogen-diluted | 1.30 | 11.4 | 0.688 | 10.2 |
| n-type silicon layer (10 nm)/ | | | | |
| n-type amophous silicon | | | | |
| (n-a-Si:H) layer (25 nm) | | | | |
| n-type amorphous silicon | 1.33 | 11.7 | 0.696 | 10.8 |
| (n-a-Si-H) layer (5 nm)/ | | | | |
| highly hydrogen-diluted | | | | |
| n-type silicon layer (30 nm) | | | | |

Referring to Table 2, when the n-type double layer structure comprising an ultrathin (5 nm) slightly hydrogen-diluted n-type amorphous silicon (n-a-Si:H) layer and highly hydrogen-diluted n-type silicon layer having a higher electrical conductivity than that of the slightly hydrogen-diluted n-type amorphous silicon (n-a-Si:H) layer is used in the second unit cell 900, it can be found that the efficiency is more improved than when only the slightly hydrogen-diluted n-type amorphous silicon (n-a-Si:H) layer is adapted.

This is because, as described in the amorphous thin film silicon solar cell, the n-type amorphous silicon layer 530a smoothen the abrupt change of the conduction band at the n/i interface and reduces the recombination loss.

However, when the slightly hydrogen-diluted n-type amorphous silicon first n layer 530a is relatively thick and the highly hydrogen-diluted n-type silicon second n layer 530b is relatively thin, it can be seen that only the fill factor (FF) is slightly increased and the efficiency is rather more reduced due to the decrease in the short circuit current. This is because when the slightly hydrogen-diluted n-type amorphous silicon first n layer 530a becomes thicker, the light absorption in the slightly hydrogen-diluted n-type amorphous silicon first n layer 530a is increased, and thus the electrical conductivity improvement caused by the highly hydrogen-diluted n-type silicon second n layer 530b is not effective. Therefore, it is desirable that the thickness of the first n layer 530a is 3 nm to 7 nm and the thickness of the second n layer 530b is 15 nm to 30 nm.

The double layer structure of the first n layer 530a and the second n layer 530b according to the second embodiment of the present invention may be applied to not only the single-junction p-i-n type thin film silicon solar cell but also the multi-junction structure. As shown in Table 2, the double layer structure increases the efficiency of the solar cell.

Regarding the triple-junction structure, a third unit cell (not shown) is further included between the first unit cell 800 and the second unit cell 900.

An n-type layer of the third unit cell may include an n-type amorphous silicon layer and an n-type silicon layer which is stacked on the n-type amorphous silicon layer. The n-type amorphous silicon layer is stacked on the i-type photoelectric conversion layer of the third unit cell and has a thickness of 3 nm to 7 nm. The n-type silicon layer has a thickness of 15 nm to 30 nm and is more highly hydrogen-diluted than the n-type amorphous silicon layer.

Likewise, an additional unit cell may be inserted between the first unit cell 800 and the second unit cell 900.

FIG. 5 shows a measurement result of Raman spectroscopy using HeNe laser with a wavelength of 633 nm.

By Raman spectroscopy, a crystal volume traction measured from the n-type layer 530 of the back side of the double-junction solar cell is 64%. Since laser with a wavelength of 633 nm transmits through the n-type layer 530 of the second unit cell 900 and reaches the i-type microcrystalline silicon photoelectric conversion layer 520, the double-junction solar cell has a crystal volume fraction greater than that of the single-junction solar cell. It is preferable that the crystal volume fraction should be 25% to 85%. If the crystal volume fraction is less than 25%, an amorphous incubation layer is formed in the i-type photoelectric conversion layer 520, and hence the long wavelength characteristics of the solar cell is deteriorated. If the crystal volume fraction is greater than 85%, the grain boundary volume of the i-type photoelectric conversion layer 520 grows and the recombination of the photo-generated carriers is increased.

Next, a manufacturing method of the thin film silicon solar cell will be described.

FIG. 7 is a flowchart showing a manufacturing method for the thin film silicon solar cell according to the embodiment of the present invention.

As shown in FIG. 7, in the manufacture of the thin film silicon solar cell according to the present invention, the front transparent electrode is formed on an insulating substrate such as glass or flexible polymer (S10). The front transparent electrode has a surface unevenness in order to improve the light trapping effect and is coated with a ZnO thin film or a SnO₂ thin film.

In the production of the thin film silicon, solar cell, patterning is performed by a laser scribing method and the like for serial connection between the unit cells. A cleaning process is performed in order to remove particles generated during the patterning process and then the substrate is loaded in a vacuum chamber of a plasma-CVD system. Subsequently, residual moisture in the substrate is removed by a preheating process.

After the preheating process, the p-type window layer and the p-type buffer layer are stacked (S20 and S30).

After the substrate is carried to a p-layer deposition chamber, the pressure of the p-layer deposition chamber reaches a base pressure close to vacuum by the operation of a high vacuum pump like a turbo molecular pump.

After the pressure of the p-layer deposition chamber reaches the base pressure, reaction gas is introduced into the deposition chamber and the pressure of the deposition chamber reaches a deposition pressure by the introduction of the reaction gas. The reaction gas includes silane (SiH₄), hydrogen (H₂), group III impurity gas, and carbon or oxygen source gas. The group III impurity gas may include diborane gas (B₂H₆), TMB (TriMethylBoron), TEB (TriEthylBoron) and the like. The carbon source gas may include methan (CH₄), ethylene (C₂H₄), acetylene (C₂H₂) and the like. The oxygen source gas may include O₂, CO₂ or the like. The flow rate of each source gas is controlled by each mass flow controller (MFC).

When the pressure of the deposition chamber reaches a predetermined deposition pressure, the pressure of the deposition chamber is maintained constant by a pressure controller, which is connected to the deposition chamber, and an angle valve. The deposition pressure is set to a value for obtaining the thickness uniformity, high quality characteristics and an appropriate deposition rate of the thin film. The deposition pressure may be equal to or greater than 0.4 Torr and equal to or less than 2.5 Torr. If the deposition pressure is less than 0.4 Torr, the thickness uniformity and deposition rate of the p-type window layer are reduced, if the deposition pressure is greater than 2.5 Torr, powder is produced at a plasma electrode within the deposition chamber or the amount of gas used is increased, and therefore the manufacturing cost is increased.

When the pressure within the deposition chamber is stabilized to the deposition pressure, the reaction gas within the deposition chamber is decomposed by means of either radio frequency plasma enhanced chemical vapor deposition (RF PECVD) using a frequency of 13.56 MHz or very high frequency plasma enhanced chemical vapor deposition (VHF PECVD) using a frequency greater than 13.56 MHz. As a result, the slightly hydrogen-diluted p-type window layer is deposited.

The thickness of the p-type window layer 30a is equal to or larger than 12 nm and equal to or less than 17 nm. If the thickness of the p-type window layer is less than 12 nm, conductivity becomes lower and a strong electric field cannot be formed in an intrinsic light absorber. Therefore, the open circuit voltage of the photovoltaic device is low. If the thickness of the p-type window layer is larger than 17 nm, the light absorption in the p-type window layer increases and the short circuit current may be reduced. Therefore, the conversion efficiency may be reduced. Since the composition of the reaction gas is maintained constant during the deposition, the hydrogen-diluted p-type window layer having a constant optical band gap is formed.

The dark conductivity of the p-type window layer according to the embodiment of the present invention may be about 1×10⁻⁶ S/cm, and the optical band gap of the p-type window layer may be about 2.0 eV. A silane concentration, i.e., an indicator of the hydrogen dilution ratio at the time of forming the p-type window layer may be equal to or greater than 4% and equal to or less than 10%. Here, the silane concentration is a ratio of a sum of the silane flow rate and the hydrogen flow rate to the silane flow rate.

The deposition of the p-type window layer is completed by turning off the power of plasma.

The buffer layer is manufactured by the following method.

Reaction gas for forming the buffer layer includes silane gas (SiH₄), hydrogen gas (H₂), group III impurity gas, carbon source gas or oxygen source gas. Since the group III impurity gas, carbon source gas and oxygen source gas have been described above, a description thereof will be omitted.

In the embodiment of the present invention, when the p-type window layer is composed of hydrogenated amorphous silicon carbide, the buffer layer is composed, of either hydrogenated amorphous silicon carbide or hydrogenated amorphous silicon oxide. Accordingly, when the carbon source gas is used to form the p-type window layer, the carbon source gas or oxygen source gas is used to form the buffer layer.

When the p-type buffer layer is formed after the p-type window layer is formed, predetermined flow rates and predetermined deposition pressures of the gases included in the reaction gas change. Therefore, the angle valve connected to the pressure controller of the deposition chamber is fully opened and the setting of the flow rate of each mass flow controller is set to the deposition flow rate of the p-type buffer layer. The deposition pressure of the p-type buffer layer may be equal to or greater 0.4 Torr and equal to or less than 2.5 Torr in consideration of the thickness uniformity, characteristics and an appropriate deposition rate of the thin film.

When the pressure of the deposition chamber is stabilized to the deposition pressure, the reaction gas is decomposed in the deposition chamber by RF plasma or VHF plasma. Here, the p-type buffer layer more highly hydrogen-diluted than the p-type window layer is deposited.

In the embodiment of the present invention, when the p-type window layer is composed of hydrogenated amorphous silicon oxide, the p-type buffer layer is composed of either hydrogenated amorphous silicon carbide or hydrogenated amorphous silicon oxide. Accordingly, when the oxygen source gas is used to form the p-type window layer, the carbon source gas or oxygen source gas is used to form the p-type buffer layer.

The i-type photoelectric conversion layer is stacked on the p-type buffer layer (S40). Various intrinsic light absorbers may be used as the i-type photoelectric conversion layer.

Here, in the p-i-n type amorphous silicon solar cell to which the two layer hydrogenated amorphous silicon carbide (p-a-SiC:H) structure of the present invention is effectively applied, there are kinds of the intrinsic light absorber, such as hydrogenated intrinsic amorphous silicon (i-a-Si:H), hydrogenated. intrinsic proto-crystalline silicon (i-pc-Si:H), hydrogenated intrinsic proto-crystalline silicon (i-pc-Si:H) multilayer, hydrogenated intrinsic amorphous silicon carbide (i-a-SiC:H), hydrogenated intrinsic proto-crystalline silicon carbide (i-pc-SiC:H), hydrogenated intrinsic proto-crystalline silicon carbide (i-pc-SiC:H) multilayer, hydrogenated intrinsic amorphous silicon oxide (i-a-SiO:H), hydrogenated intrinsic proto-crystalline silicon oxide (i-pc-SiO:H), hydrogenated intrinsic proto-crystalline silicon oxide (i-pc-SiO:H) multilayer and the like.

The solar cell, which is based on the p-i-n type amorphous silicon to which the two layer p-a-SiC:H structure is applied, is used as the top cell, so that the high efficient double or triple-junction solar cell can be manufactured.

Regarding a p-i-n-p-i-n type double-junction solar cell, there are kinds of the intrinsic light absorber of the bottom cell such, as hydrogenated intrinsic amorphous silicon. (i-a-Si:H), hydrogenated intrinsic amorphous silicon germanium (i-a-SiGe:H), hydrogenated intrinsic proto-crystalline silicon germanium (i-pc-SiGe:H), hydrogenated intrinsic nano-crystalline silicon (i-nc-Si:H), hydrogenated intrinsic microcrystalline silicon (i-μc-Si:H), hydrogenated intrinsic microcrystalline silicon germanium (i-μc-SiGe:H) and the like.

Regarding a p-i-n-p-i-n-p-i-n type triple-junction solar cell, there are kinds of the intrinsic light absorber of a middle cell, such as hydrogenated intrinsic amorphous silicon germanium (i-a-SiGe:H), hydrogenated intrinsic proto-crystalline silicon germanium (i-pc-SiGe:H), hydrogenated intrinsic nano-crystalline silicon (i-nc-Si:H), hydrogenated intrinsic microcrystalline silicon (i-μc-Si:H), hydrogenated intrinsic microcrystalline silicon germanium carbon (i-μc-SiGeC:H) and the like. There are kinds of the intrinsic light absorber of the bottom cell, such as hydrogenated intrinsic amorphous silicon germanium (i-a-SiGe:H), hydrogenated intrinsic proto-crystalline silicon germanium (i-pc-SiGe:H), hydrogenated intrinsic nano-crystalline silicon (i-nc-Si:H), hydrogenated intrinsic microcrystalline silicon (i-μc-Si:H), hydrogenated intrinsic microcrystalline silicon germanium (i-μc-SiGe:H) and the like.

Subsequently, the slightly hydrogen-diluted n-type amorphous silicon first n layer, the highly hydrogen-diluted n-type silicon second n layer and the metal back electrode layer are stacked on an i-type intrinsic light absorber, and then the thin film silicon solar cell is manufactured (S50 S60, S70).

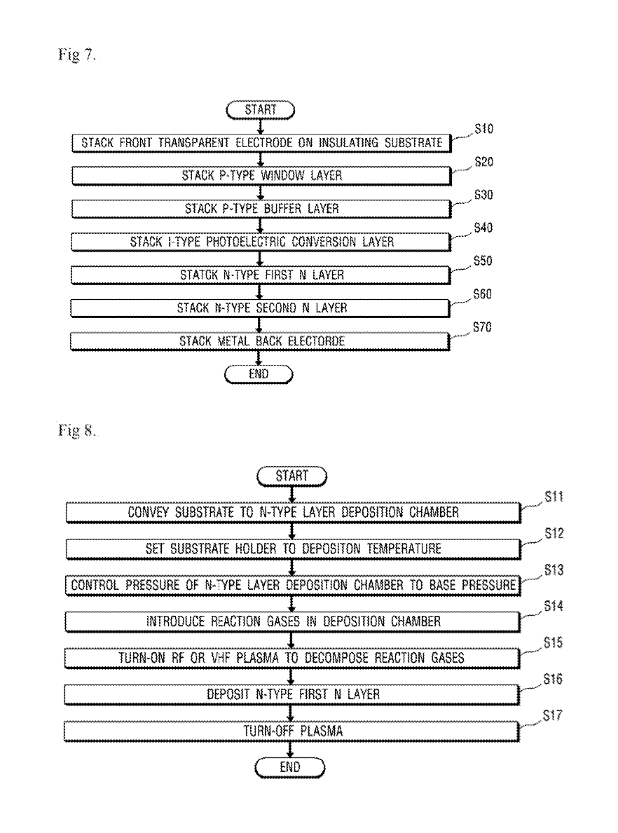

FIG. 8 is a flowchart showing a manufacturing method for a first n layer according to the embodiment of the present invention.

As shown in FIG. 8, a method for manufacturing the slightly hydrogen-diluted n-type amorphous silicon first n layer which is deposited on the i-type photoelectric conversion layer is as follows.

First, the substrate on which the i-type photoelectric conversion layer has been stacked is transferred to an n-layer deposition chamber in order to deposit the n-type layer (S11).

Here, the temperature of a substrate holder of the n-layer deposition chamber should be controlled to be set to a deposition temperature (S12). The deposition temperature corresponds to an actual temperature of the substrate at which the slightly hydrogen-diluted n-type amorphous silicon first n layer is being deposited. It is suitable that the deposition temperature should be 100° C. to 200° C. If the deposition temperature is too low, the deposition rate of the thin film is reduced and a poor thin film having a high defect density is deposited. If the deposition temperature is too high, the evolution of hydrogen from the i-type photoelectric conversion layer proceeds, and thus the characteristic of the solar cell is deteriorated. Also, a flexible substrate may be transformed.

With regard to zinc oxide (ZnO), hydrogen functioning as an n-type impurity is evoluted from a grain boundary or the surface of the zinc oxide at a temperature higher than 200° C. and causes the increase in the resistivity. Hereby, there is an accompanying problem that the efficiency of the solar cell is reduced.

After the substrate on which the i-type photoelectric conversion layer has been stacked is carried to the n-layer deposition chamber, the pressure of the n-layer deposition chamber reaches a base pressure by the operation of a high vacuum pump like a turbo molecular pump, and thereby the n-layer deposition chamber becomes in a vacuum state (S13). Here, it is recommended that the base pressure is 10⁻⁷ Torr to 10⁻⁵ Torr. A high quality thin film which is less contaminated by oxygen, nitrogen or the like may be deposited via the reduction of the base pressure. However, a deposition time becomes longer and the throughput is reduced. The greater the base pressure is, the high quality thin film is more contaminated by oxygen, nitrogen or the like. Therefore, a high quality thin film cannot be obtained.

After the pressure of the deposition chamber reaches the base pressure, the reaction gas is introduced into the deposition chamber and the pressure of the deposition chamber reaches a deposition pressure (S14). The reaction gas includes silane (SiH₄), hydrogen (H₂) and phosphine (PH₃).

When the pressure of the deposition chamber reaches a predetermined deposition pressure, the pressure of the deposition chamber is constantly maintained to a predetermined pressure value by a pressure controller, which is connected to the deposition chamber, and an angle valve. The deposition pressure is set to a value for obtaining the thickness uniformity, high quality characteristics and an appropriate deposition rate of the thin film. It is recommended that the deposition pressure is 0.4 Torr to 2 Torr. If the deposition pressure is low, the thickness uniformity and deposition rate are reduced. If the deposition pressure is too high, powder is produced at a plasma electrode or the amount of gas used is increased, and therefore a running cost is increased.

When the pressure within the deposition chamber is stabilized to the deposition pressure, the reaction gas is decomposed by generating RF or VHF plasma within the deposition chamber (S15). Then, the slightly hydrogen-diluted n-type amorphous silicon first n layer is deposited on the substrate coated with a patterned transparent electrode (S16).

The thickness of the slightly hydrogen-diluted n-type amorphous silicon first n layer should be 3 nm to 7 nm. If the thickness is too thin, the function to reduce the recombination at the n/i interface cannot be correctly performed. If the thickness is too thick, the light absorption by the slightly hydrogen-diluted n-type amorphous silicon first n layer increases and the short circuit current is reduced. Furthermore, the fill factor is reduced by the increase in the serial resistance, and thus the conversion efficiency is reduced.

Since the flow rates of the source gases are maintained constant during the deposition, the slightly hydrogen-diluted n-type amorphous silicon first n layer having a constant optical band gap is formed. A hydrogen dilution ratio (i.e., the flow rate of hydrogen gas/the flow rate of SiH₄) is selected within a range between 0 and 50. If the hydrogen dilution ratio is greater than 50, the i-type photoelectric conversion layer is damaged by high energy hydrogen ions. Also, the disorder within the thin film is increased, and thus dangling bond density is increased and the function to reduce the electron-hole recombination at the n/i interface cannot be correctly performed.

Lastly, the deposition of the slightly hydrogen-diluted n-type amorphous silicon first n layer is completed by turning off the power of plasma (S17).

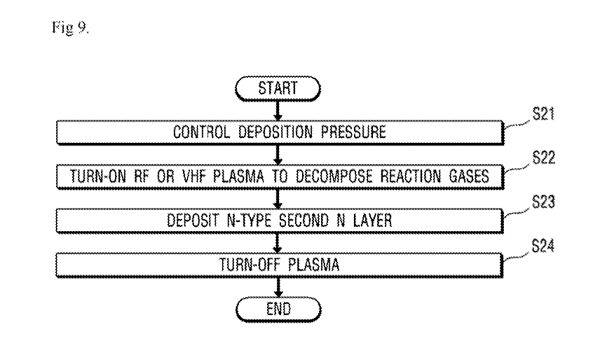

FIG. 9 is a flowchart showing a manufacturing method for a second n layer according to the embodiment of the present invention.

As shown in FIG. 9, a method for manufacturing the highly hydrogen-diluted n-type silicon second n layer on the slightly hydrogen-diluted n-type amorphous silicon first n layer is as follows.

First, the kind of the source gas used for the highly hydrogen-diluted n-type silicon second n layer is the same as the kind of the source gas used for the slightly hydrogen-diluted n-type amorphous silicon first n layer,

However, the predetermined flow rate and the predetermined deposition pressure are changed depending on each source gas. Therefore, after the deposition of the slightly hydrogen-diluted n-type amorphous silicon first n layer is completed by turning off the power of plasma, the angle valve connected to the pressure controller is fully opened and the setting of the flow rate of each mass flow controller is set to a flow rate for the deposition of the highly hydrogen-diluted n-type silicon second n layer.

Here, the pressure of the pressure controller is set to a deposition pressure of the highly hydrogen-diluted n-type silicon second n layer, and the deposition pressure is controlled through the angle valve control (S21). The deposition pressure is set to a value for obtaining the thickness uniformity, high quality characteristics and an appropriate deposition rate of the thin film. It is recommended that the deposition pressure is 1 Torr to 7 Torr. If the deposition pressure is low, the thickness uniformity and deposition rate are reduced. If the deposition pressure is too high, powder is produced at a plasma electrode or the amount of gas used is increased, and thus a running cost is increased.

When the pressure within the deposition chamber is stabilized to the deposition pressure, the reaction gas is decomposed by generating RF or VHF plasma within the deposition chamber (S22). Then, the highly hydrogen-diluted n-type silicon second n layer is deposited on the slightly hydrogen-diluted n-type amorphous silicon first n layer (S23).

The thickness of the highly hydrogen-diluted n-type silicon second n layer should be 15 nm to 30 nm. If the thickness is too thin, the electrical conductivity is low and a strong electric field by an intrinsic light absorber cannot be formed. Thus, the open circuit voltage of the solar cell becomes lower. If the thickness is too thick, the light absorption by the highly hydrogen-diluted n-type silicon second n layer increases and the short circuit current is reduced. Therefore, the conversion efficiency is reduced. Since the composition of the source gas is maintained constant during the deposition, the highly hydrogen-diluted n-type silicon second n layer having a constant optical band gap is formed.

A hydrogen dilution ratio (i.e., the flow rate of hydrogen gas/the flow rate of SiH₄) of the highly hydrogen-diluted n-type silicon second n layer is selected within a range between 50 and 400. If the hydrogen dilution ratio is too low, the electrical conductivity is reduced. If the hydrogen dilution ratio is too high, the deposition rate becomes lower and the manufacturing cost increases.

Lastly, the deposition of the highly hydrogen-diluted n-type silicon second n layer is completed by turning off the power of plasma (S24). The mass flow controllers block the flows of all the reaction gas and the angle valve connected to the pressure controller is fully opened, and thus the residual source gas in the deposition chamber is sufficiently evacuated to an exhaust line. Then, the next process in which the back electrode is prepared is subsequently performed.

Accordingly, the silicon thin film solar cell manufactured through the aforementioned process makes use of a double layer in which the slightly hydrogen-diluted n-type amorphous silicon first n layer and the highly hydrogen-diluted n-type silicon second n layer are stacked in the order listed. With this, the electron-hole recombination at the n/i interface of the p-i-n type silicon thin film solar cell is effectively reduced, and therefore the photoelectric conversion efficiency of the thin film silicon solar cell is improved.

As described above, it will be appreciated by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A thin film silicon solar cell comprising:
a front transparent electrode stacked on a transparent insulating substrate;
a p-type layer stacked on the front transparent electrode;
an i-type photoelectric conversion layer stacked on the p-type layer;
an n-type layer stacked on the i-type photoelectric conversion layer; and
a metal back electrode layer stacked on the n-type layer,
wherein the n-type layer includes:
an n-type amorphous silicon first n layer which is stacked on the i-type photoelectric conversion layer and has a thickness of 3 nm to 7 nm; and
an n-type silicon second n layer which is stacked on the first n layer and has a thickness of 15 nm to 30 nm and is more highly hydrogen-diluted than the first n layer.

2. The thin film silicon solar cell of claim 1, wherein an impurity concentration of the first n layer is higher than that of the second n layer.

3. The thin film silicon solar cell of claim 2, wherein impurity concentrations of the second n layer and the first n layer are equal to or higher than 1×10¹⁹/cm³ and equal to or less than 1×10²¹/cm³.

4. The thin film silicon solar cell of claim 1, wherein a hydrogen concentration of the first n layer is less than that of the second n layer.

5. The thin film silicon solar cell of claim 4, wherein the hydrogen concentrations of the second n layer and the first n layer are equal to or more than 5 atomic % and equal to or less than 25 atomic %.

6. The thin film silicon solar cell of claim 1, wherein, when the n-type layer is measured by Raman spectroscopy by irradiating laser with a wavelength of 633 nm to the back side of the n-type layer, a crystal volume fraction is equal to or less than 25%.

7. The thin film silicon solar cell of claim 1, wherein the second n layer comprises at least one of oxygen, nitrogen or carbon as a non-silicon element, and wherein an average content of the non-silicon element is equal to or more than 10 atomic % and equal to or less than 50 atomic %.

8. The thin film silicon solar cell of claim 1, wherein the second n layer is an amorphous silicon layer or a microcrystalline silicon layer.

9. The thin film silicon solar cell of claim 1, further comprising a back reflector which is located between the n-type layer and the metal back electrode layer.

10. The thin film silicon solar cell of claim 1, wherein the p-type layer comprises:
a hydrogenated p-type silicon carbide (p-a-SiC:H) window Saver which is stacked on the front transparent electrode; and
a hydrogenated p-type silicon carbide (p-a-SiC:H) buffer layer which is stacked between the window layer and the i-type photoelectric conversion layer.

11. A thin film silicon solar cell comprising;
a front transparent electrode stacked on a transparent insulating substrate;
a first unit cell which is stacked on the transparent electrode and includes a p-type layer, an i-type photoelectric conversion layer and an n-type layer;
a second unit cell which is stacked on the first unit cell and includes a p-type layer, an i-type photoelectric conversion layer and an n-type layer; and
a metal back electrode layer stacked on the second unit cell,
wherein the n-type layer of the second unit cell includes:
an n-type amorphous silicon first n layer which is stacked on the i-type photoelectric conversion layer of the second unit cell and has a thickness of 3 nm to 7 nm; and
an n-type silicon second n layer which is stacked on the first n layer and has a thickness of 15 nm to 30 nm and is more highly hydrogen-diluted than the first n layer.

12. The thin film silicon solar cell of claim 11, wherein an impurity concentration of the first n layer is higher than that of the second n layer.

13. The thin film silicon solar cell of claim 12, wherein impurity concentrations of the second n layer and the first n layer are equal to or higher than 1×10¹⁹/cm³ and equal to or less than 1×10²¹/cm³.

14. The thin film silicon solar cell of claim 11, wherein a hydrogen concentration of the first n layer is less than that of the second n layer.

15. The thin film silicon solar cell of claim 14, wherein the hydrogen concentrations of the second n layer and the first n layer are equal to or more than 5 atomic % and equal to or less than 25 atomic %.

16. The thin film silicon solar cell of claim 11, wherein, when the n-type layer is measured by Raman spectroscopy by irradiating laser with a wavelength of 633 nm to the back side of the second unit cell, a crystal volume fraction is equal to or greater than 25% and equal to or less than 85%.

17. The thin film silicon solar cell of claim 11, wherein the second n layer comprises oxygen, nitrogen or carbon as a non-silicon element, and wherein an average content of the non-silicon element is equal to or more than 10 atomic % and equal to or less than 50 atomic %.

18. The thin film silicon solar cell of claim 11, wherein the second n layer is an amorphous silicon layer or a microcrystalline silicon layer.

19. The thin film silicon solar cell of claim 11, wherein a hydrogen dilution ratio of the first n layer is equal to or greater than 0 and equal to or less than 50, and wherein a hydrogen dilution ratio of the second n layer is equal to or greater than 50 and equal to or less than 400.

20. The thin film silicon solar cell of claim 11, further comprising a back reflector which is located between the second unit cell and the metal back electrode layer.

21. The thin film silicon solar cell of claim 11, wherein the n-type layer of the first unit cell comprises:
an n-type amorphous silicon layer which is stacked on the i-type photoelectric conversion layer of the first unit cell and has a thickness of 3 nm to 7 nm; and
an n-type silicon layer which is stacked on the n-type amorphous silicon layer and has a thickness of 15 nm to 30 nm and is more highly hydrogen-diluted than the n-type amorphous silicon layer.

22. The thin film silicon solar cell of claim 11, further comprising at least one unit cell which is stacked between the first unit cell and the second unit cell and includes the p-type layer, the i-type photoelectric conversion layer and the n-type layer.

23. The thin film silicon solar cell of claim 22, wherein at least any one n-type layer among the at least one unit cell comprises:
an n-type amorphous silicon layer which is stacked on the i-type photoelectric conversion layer of a corresponding unit cell and has a thickness of 3 nm to 7 nm; and
an n-type silicon layer which is stacked on the n-type amorphous silicon layer and has a thickness of 15 nm to 30 nm and is more highly hydrogen-diluted than the n-type amorphous silicon layer.
